(19) United States
(12) Patent Application Publication
(10) Pub. No.: US 2025/0102748 A1
(43) Pub. Date: Mar. 27, 2025

(54) SEMICONDUCTOR PACKAGE

(71) Applicant: Samsung Electronics Co., Ltd., Suwon-si (KR)

(72) Inventors: Junghoon KANG, Suwon-si (KR); Daegon KIM, Suwon-si (KR)

(73) Assignee: Samsung Electronics Co., Ltd., Suwon-si (KR)

(21) Appl. No.: 18/676,584

(22) Filed: May 29, 2024

(30) Foreign Application Priority Data
Sep. 21, 2023 (KR) 10-2023-0126403

(51) Int. Cl. G02B 6/42; G02B 6/43

(52) U.S. Cl. CPC G02B 6/4283; G02B 6/4238; G02B 6/4239; G02B 6/4243; G02B 6/43

(57) ABSTRACT

A semiconductor package includes a redistribution layer on a substrate, a semiconductor chip on the redistribution layer, and a stack structure on the redistribution layer and spaced apart from the semiconductor chip in a horizontal direction, wherein the stack structure includes an optical integrated circuit chip, the first optical integrated circuit chip includes a first region adjacent to the semiconductor chip and a second region adjacent to an outer portion of the substrate, and the optical integrated circuit chip defines a first notch and a first groove in the second region, the first groove recessed upwards in a vertical direction from a lower surface of the optical integrated circuit chip, the first groove recessed downwards in the vertical direction from an upper surface of the optical integrated circuit chip.

### CROSS-REFERENCE TO RELATED APPLICATIONS

This application is based on and claims priority under 35 U.S.C. § 119 to Korean Patent Application No. 10-2023-0126403, filed on Sep. 21, 2023, in the Korean Intellectual Property Office, the disclosure of which is incorporated by reference herein in its entirety.

### BACKGROUND

The inventive concepts relate to a semiconductor package, and more particularly, to a semiconductor package including an optical integrated circuit chip.

The advantages of semiconductor packages are increasingly being utilized to improve the functionality of electronic devices and integrate components. A semiconductor package allows various integrated circuits, such as memory chips or logic chips, to be mounted on a package substrate. Recently, in an environment where data traffic is increasing in data centers and communication infrastructure, research on semiconductor packages including an optical integrated circuit chip continues.

### SUMMARY

Some example embodiments of the inventive concepts provide semiconductor packages having an improved power efficiency.

Some example embodiments of the inventive concept provide semiconductor packages having higher data processing rate and increased memory capacity.

In addition, objectives to be solved by the inventive concepts are not limited to the above-mentioned ones, and other objectives may be clearly understood by those skilled in the art from the description below.

According to an example embodiment of the inventive concepts, a semiconductor package includes a redistribution layer on a substrate, a semiconductor chip on the redistribution layer, and a stack structure on the redistribution layer, the stack structure spaced apart from the semiconductor chip in a horizontal direction, wherein the stack structure includes a first optical integrated circuit chip and a second optical integrated circuit chip on the first optical integrated circuit chip, wherein each of the first optical integrated circuit chip and the second optical integrated circuit chip includes a first region and a second region, among the first region and the second region, the first region is relatively adjacent to the semiconductor chip and the second region is relatively adjacent to an outer portion of the substrate, and the first optical integrated circuit chip defines a first notch and a first groove in the second region, the first notch recessed upwards in a vertical direction from a lower surface of the first optical integrated circuit chip, the first groove recessed downwards in the vertical direction from an upper surface of the first optical integrated circuit chip.

According to an example embodiment of the inventive concepts, a semiconductor package includes a redistribution layer on a substrate, a semiconductor chip on the redistribution layer, a first stack structure on the redistribution layer and spaced apart from the semiconductor chip in a first horizontal direction, and a plurality of first optical fibers coupled to the first stack structure, wherein the first stack structure includes a plurality of optical integrated circuit chips stacked vertically with respect to each other, and each of the first optical fibers is spaced apart from another in the vertical direction.

According to an example embodiment of the inventive concepts, a semiconductor package includes a redistribution layer on a substrate, a semiconductor chip on the redistribution layer, a stack structure on the redistribution layer and spaced apart from the semiconductor chip in a horizontal direction, and an electronic integrated circuit chip on the stack structure, wherein the stack structure includes a first optical integrated circuit chip, the first optical integrated circuit chip includes a first region and a second region, and among the first region and the second region, the first region being relatively adjacent to the semiconductor chip and the second region being relatively adjacent to an outer portion of the substrate, and the first optical integrated circuit chip includes a first body including an optical integrated circuit and an electronic integrated circuit, a first upper pad on an upper surface of the first body and a first lower pad on a lower surface of the first body, a through via penetrating the first body and connected to the first upper pad and the first lower pad, and the first optical integrated circuit chip defining a first notch and a first groove in the second region, the first notch recessed upwards in a vertical direction from a lower surface of the first optical integrated circuit chip, the first groove that is recessed downwards in the vertical direction from an upper surface of the first optical integrated circuit chip.

In the semiconductor packages according to the above example embodiments of the inventive concepts, the optical integrated circuit chip of the stack structure may define a groove in an upper portion thereof and a notch in a lower portion thereof. Accordingly, an optical fiber may be coupled between the groove of one of the plurality of optical integrated circuit chips and the notch of the optical integrated circuit chip thereon. Additionally, one optical integrated circuit chip and another optical integrated circuit chip thereon may be hybrid-bonded to each other. Accordingly, a plurality of optical integrated circuit chips may be stacked in a vertical direction, thereby increasing the number of optical integrated circuit chips included in the stack structure within the semiconductor package. For the above reasons, the number of channels that the semiconductor package may process may be increased, thereby increasing the data processing speed of the semiconductor package and increasing the memory capacity.

### BRIEF DESCRIPTION OF THE DRAWINGS

Example embodiments will be more clearly understood from the following detailed description taken in conjunction with the accompanying drawings in which:

FIG. 1 is a plan view illustrating a semiconductor package according to an example embodiment;

FIG. 2 is a cross-sectional view taken along line A-A′ of FIG. 1;

FIG. 3 is an enlarged view of a portion PP of FIG. 2 according to an example embodiment;

FIG. 4 is a diagram illustrating a portion of a cross-section taken along line B-B′ of FIG. 1 according to an example embodiment;

FIG. 5 is a diagram illustrating a portion of the cross-section taken along line B-B′ of FIG. 1 according to an example embodiment;

FIG. 6 is a diagram illustrating a portion of the cross-section taken along line B-B′ of FIG. 1 according to an example embodiment;

FIG. 7 is a diagram illustrating a portion of the cross-section taken along line B-B′ of FIG. 1 according to an example embodiment;

FIG. 8 is an enlarged view of the portion PP of FIG. 2 according to an example embodiment; and

FIG. 9 is a plan view illustrating a semiconductor package according to an example embodiment.

### DETAILED DESCRIPTION

As the inventive concepts allow for various changes and numerous example embodiments, some example embodiments will be illustrated in the drawings and described in detail in the written description. However, this is not intended to limit example embodiments to a specific disclosure form.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

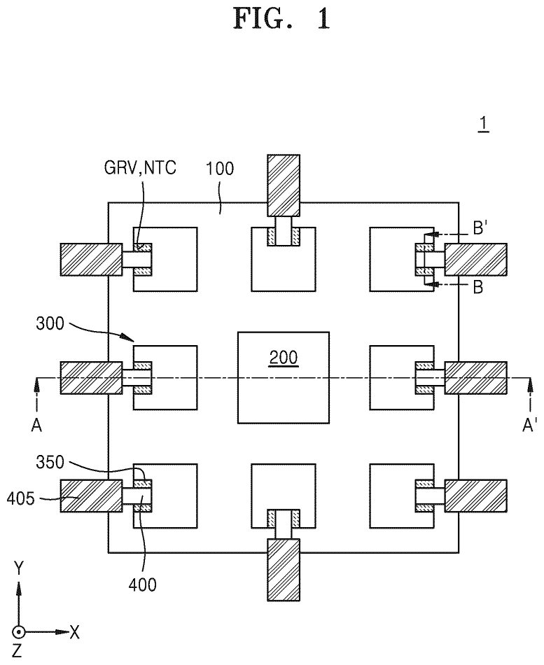

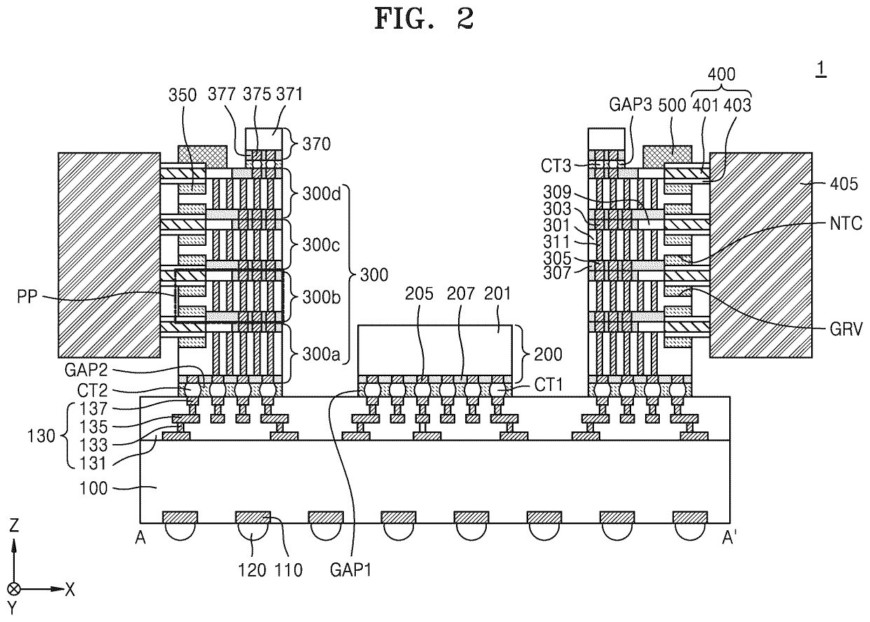

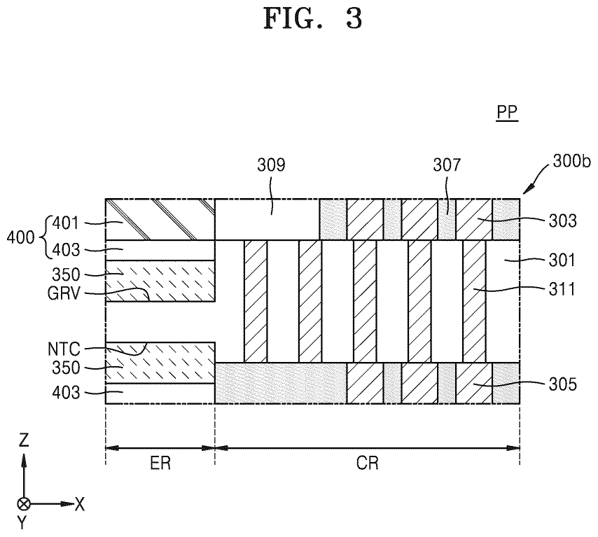

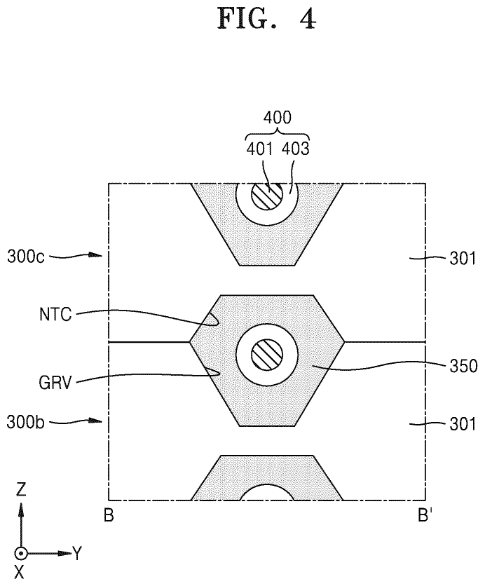

FIG. 1 is a plan view illustrating a semiconductor package 1 according to an example embodiment. FIG. 2 is a cross-sectional view taken along line A-A′ of FIG. 1. FIG. 3 is an enlarged view of a portion PP of FIG. 2. FIG. 4 is a diagram illustrating a portion of a cross-section taken along line B-B′ of FIG. 1 according to an example embodiment.

Referring to FIGS. 1 and 2, the semiconductor package 1 may include a substrate 100, a redistribution layer 130, a semiconductor chip 200, a stack structure 300, and an optical fiber 400.

The substrate 100 may be provided. The substrate 100 may include a package substrate such as a printed circuit board (PCB). Although not shown, conductive wires may be disposed inside the substrate 100. An external connection pad 110 connected to the conductive wires may be disposed on a lower surface of the substrate 100. An external connection terminal 120 may be disposed below the external connection pad 110. The external connection terminal 120 may be connected to the conductive wires inside the substrate 100 through the external connection pad 110. The external connection terminal 120 may be configured to transmit signals from the outside to the substrate 100. For example, when a motherboard is provided under the substrate 100, electrical connection between the motherboard and the semiconductor package 1 may be made through the external connection terminal 120. The conductive wires and the external connection pad 110 may include conductive metal. The external connection terminal 120 may include, for example, a solder ball.

Hereinafter, unless specifically defined, a direction parallel to an upper surface of the substrate 100 is defined as a first horizontal direction X, and a direction parallel to the upper surface of the substrate 100 and perpendicular to the first horizontal direction X is defined as a second horizontal direction Y, and a direction perpendicular to the upper surface of the substrate 100 is defined as a vertical direction Z.

The redistribution layer 130 may be disposed on the upper surface of the substrate 100. The redistribution layer 130 may include an insulating layer 131, a vertical via 133, a wiring line 135, and a redistribution pad 137 within the insulating layer 131.

The insulating layer 131 may include a single layer or multiple layers. The insulating layer 131 may include, for example, a photosensitive insulating material (e.g., a photo imageable dielectric (PID)). The vertical via 133 may connect different wiring lines 135 spaced apart from each other in the vertical direction Z. A length of the vertical via 133 in the vertical direction Z may be greater than lengths thereof in the first and second horizontal directions X and Y. A length of the wiring line 135 in the first and second horizontal directions X and Y may be greater than a length thereof in the vertical direction Z. The redistribution pad 137 may be disposed on an upper surface of the redistribution layer 130. Some of the vertical vias 133 may connect an uppermost wiring line 135 to the redistribution pad 137. In some example embodiments, the vertical vias 133 and the wiring lines 135 may include copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof.

The semiconductor chip 200 may be disposed on the redistribution layer 130. From a plan view, the semiconductor chip 200 may be arranged at a center or a central area of the substrate 100 and the redistribution layer 130. The semiconductor chip 200 may be, for example, an application specific integrated circuit (ASIC) or a system semiconductor. The semiconductor chip 200 may perform, for example, calculation, control, and/or information processing of electrical information.

The semiconductor chip 200 may include a first body 201, a connection pad 205, and a first passivation layer 207. The first body 201 may be a portion including a semiconductor substrate and an integrated circuit. The connection pad 205 may be connected to an integrated circuit in the first body 201 and may be disposed on a lower surface of the first body 201. The first passivation layer 207 may be disposed on the lower surface of the first body 201 and may fill a space between a plurality of connection pads 205. The first passivation layer 207 may not cover a lower surface of the connection pad 205. The connection pad 205 may include conductive metal. The first passivation layer 207 may include an insulating material such as silicon oxide.

A first connection terminal CT1 may be disposed between the semiconductor chip 200 and the redistribution layer 130. The first connection terminal CT1 may be connected to the redistribution pad 137 of the redistribution layer 130 and the connection pad 205 of the semiconductor chip 200. The semiconductor chip 200 and the redistribution layer 130 may be electrically connected to each other through the first connection terminal CT1. A first gap fill GAP1 may be disposed between the semiconductor chip 200 and the redistribution layer 130 and fill a space between the plurality of first connection terminals CT1. The first gap fill GAP1 may mitigate or prevent electrical short circuits between the plurality of first connection terminals CT1. The first connection terminal CT1 may include, for example, a solder bump. The first gap fill GAP1 may include an insulating material. In an example embodiment, the first gap fill GAP1 may be omitted.

From a plan view, a plurality of stack structures 300 surrounding the semiconductor chip 200 may be disposed on the redistribution layer 130. The plurality of stack structures 300 may be spaced apart from the semiconductor chip 200 in the first horizontal direction X or the second horizontal direction Y. Hereinafter, one stack structure 300 will be described, but this description may equally apply to the other stack structures 300.

The stack structure 300 may include a plurality of optical integrated circuit chips 300a, 300b, 300c, and 300d stacked in the vertical direction Z. Hereinafter, one optical integrated circuit chip 300b will be described, but the description may also be applied to the other optical integrated circuit chips 300a, 300c, and 300d, unless otherwise specified.

The optical integrated circuit chip 300b may include a circuit in which an optical integrated circuit element is combined with an electrical integrated circuit element. The optical integrated circuit chip 300b may refer to a device for converting optical signals to electrical signals or/and converting electrical signals to optical signals. The optical integrated circuit chip 300b may include a second body 301, an upper pad 303, a lower pad 305, a second passivation layer 307, a waveguide 309, and a through via 311.

The second body 301 may include a semiconductor substrate, such as silicon (Si) or germanium (Ge). The second body 301 may include an optical-electrical conversion portion. The second body 301 may be a portion including a circuit in which an optical integrated circuit element is combined with an electrical integrated circuit element.

The upper pad 303 and the waveguide 309 may be disposed on an upper surface of the second body 301. The second passivation layer 307 may fill a space between the plurality of upper pads 303 and a space between the upper pad 303 and the waveguide 309. The second passivation layer 307 may not cover an upper surface of the upper pad 303. The upper pad 303 may include conductive metal.

The lower pad 305 may be disposed on a lower surface of the second body 301. The second passivation layer 307 may fill a space between the plurality of lower pads 305. The second passivation layer 307 may not cover a lower surface of the lower pad 305. The lower pad 305 may include conductive metal.

The through via 311 may penetrate the second body 301. The through via 311 may be connected to integrated circuits, the upper pad 303, the lower pad 305, and/or the waveguide 309 in the second body 301. The upper pad 303 and the lower pad 305 may be connected to each other through the through via 311.

The waveguide 309 may include, for example, a silicon waveguide. The waveguide 309 may perform a function of moving light generated externally or generated from the optical integrated circuit chip 300b. Further, the waveguide 309 may include an optical component. The optical component in the waveguide 309 may convert light into an electrical signal or convert an electrical signal into light. In some example embodiments, the optical component may perform a function of amplifying and controlling light or electrical signals. Light transmitted through the waveguide 309 may be converted into an electrical signal and transmitted to the integrated circuits inside the optical integrated circuit chip 300b through the through via 311. Light transmitted through the waveguide 309 may be converted into an electrical signal and transmitted to the other optical integrated circuit chips 300a, 300c, and 300d through the through via 311.

One optical integrated circuit chip 300b may be electrically connected to another optical integrated circuit chip 300c thereon through the upper pad 303 of one optical integrated circuit chip 300b and the lower pad 305 of the other optical integrated circuit chip 300c. The upper pad 303 of one optical integrated circuit chip 300b and the lower pad 305 of the other optical integrated circuit chip 300c may contact each other. The second passivation layer 307 included on one optical integrated circuit chip 300b and the second passivation layer 307 included under the other optical integrated circuit chip 300c may contact each other. That is, one optical integrated circuit chip 300b and another optical integrated circuit chip 300c may be hybrid-bonded to each other. Hybrid bonding refers to bonding where the upper pad 303 and the lower pad 305 contact each other and the second passivation layers 307 of each of the optical integrated circuit chips 300b and 300b contact each other, so that one optical integrated circuit chip 300b and another optical integrated circuit chip 300c are bonded to each other.

Referring to FIGS. 1 to 3, the optical integrated circuit chip 300b may include a center region (or alternatively referred to as a first region) CR and an edge region (or alternatively referred to as a second region) ER. The center region CR may be a portion of the optical integrated circuit chip 300b adjacent to the semiconductor chip 200 than an outer edge of the substrate 100, and the edge region ER may be another portion of the optical integrated circuit chip 300b in a direction away from the center region CR from the semiconductor chip 200. In other words, the edge region ER may refer to a portion adjacent to an outer edge of the substrate 100 than a center portion of the substrate 100.

The optical integrated circuit chip 300b may include a groove GRV and a notch NTC in the edge region ER. The groove GRV may be a portion recessed downward in the vertical direction Z (e.g., a downward direction) from an upper surface of the optical integrated circuit chip 300b. The notch NTC may be a portion recessed upward from a lower surface of the optical integrated circuit chip 300b in the vertical direction Z (e.g., an upward direction). A bottom surface of the groove GRV and a top surface of the notch NTC may be spaced apart from each other. Due to the groove GRV and the notch NTC, a thickness of the second body 301 in the vertical direction Z in the edge region ER may be less than a thickness of the second body 301 in the vertical direction Z in the center region CR. A vertical level of the bottom surface of the groove GRV may be lower than a vertical level of the upper surface of the second body 301. A vertical level of the top surface of the notch NTC may be higher than a vertical level of the lower surface of the second body 301.

Referring to FIG. 4, a sidewall of the groove GRV of the optical integrated circuit chip 300b may have a certain angle with the upper surface of the second body 301, and the bottom surface of the groove GRV may be parallel to the upper surface of the second body 301. The groove GRV may have a V-shaped cross-section with a flat bottom surface. A sidewall of the notch NTC of the optical integrated circuit chip 300b may have a certain angle with the lower surface of the second body 301. The top surface of the notch NTC may be parallel to the lower surface of the second body 301. The notch NTC may have an inverted V-shaped cross-section with a flat top surface. An inverted V-shape may be a shape in which V is rotated 180 degrees around a direction in which the shape enters the ground.

The groove GRV of one optical integrated circuit chip 300b and the notch NTC of another optical integrated circuit chip 300c thereon may overlap each other in the vertical direction Z. A maximum horizontal width of the groove GRV of one optical integrated circuit chip 300b may be substantially equal to a maximum horizontal width of the notch NTC of another optical integrated circuit chip 300c thereon. The optical fiber 400 may be disposed between the groove GRV of one optical integrated circuit chip 300b and the notch NTC of another optical integrated circuit chip 300c thereon. The optical fiber 400 may be arranged within the groove GRV and/or within the notch NTC.

However, the lowermost optical integrated circuit chip 300a may not include the notch NTC. This may be because the optical fiber 400 is not coupled to any optical integrated circuit chip under the lowermost optical integrated circuit chip 300a.

Referring to FIGS. 2 to 4, an optical resin 350 may surround the optical fiber 400 and fill the remaining space of the groove GRV and the notch NTC. The optical resin 350 may perform a function of physically protecting the optical fiber 400 from the outside and assisting optical coupling between the optical fiber 400 and the waveguide 309. The optical resin 350 may include materials such as acrylic resin, epoxy resin, and polyurethane resin.

The optical fiber 400 may include a core 401 and a cladding 403. The core 401 may have, for example, a cylindrical shape. The cladding 403 may surround the core 401. A refractive index of the core 401 may be higher than that of the cladding 403. The core 401 and the cladding 403 may include silicate glass or plastic. Plastics may include, for example, polymethylmethacrylate (PMMA), polycarbonate, fluoropolymer, polyethylene, polyimide, and/or polyester (PET).

The optical fiber 400 may be coupled to the stack structure 300 in a direction from the edge region ER to the center region CR.

A plurality of optical fibers 400 may be provided. The plurality of optical fibers 400 may be arranged apart from each other in the vertical direction Z and be optically coupled to corresponding ones of the optical integrated circuit chips 300a, 300b, 300c, and 300d, respectively. The optical fibers 400 may be connected to a bracket 405. The bracket 405 may have a function of fixing the optical fibers 400 that are arranged apart from each other in the vertical direction Z and assisting alignment between the optical fibers 400 and the optical integrated circuit chips 300a, 300b, 300c, and 300d. One bracket 405 may be disposed to correspond to one stack structure 300.

A second connection terminal CT2 may be disposed between the lowermost optical integrated circuit chip 300a and the redistribution layer 130. The second connection terminal CT2 may be connected to the lower pad 305 of the lowermost optical integrated circuit chip 300a and the redistribution pad 137 of the redistribution layer 130. The stack structure 300 may be electrically connected to the redistribution layer 130 through the second connection terminal CT2. A second gap fill GAP2 may fill a space between the lower pads 305 of the lowermost optical integrated circuit chip 300a. The second gap fill GAP2 may have a function of mitigating or preventing electrical short circuits between the second connection terminals CT2. The second connection terminal CT2 may include, for example, a solder bump. The second gap fill GAP2 may include an insulating material. In an example embodiment, the second gap fill GAP2 may be omitted.

Although not shown, an interposer may be disposed between the lowermost optical integrated circuit chip 300a and the redistribution layer 130. The interposer may perform a function of redistributing electrical signals from the lowermost optical integrated circuit chip 300a. The interposer may include a silicon interposer, but the inventive concepts are not limited thereto. When an interposer is included, the second connection terminal CT2 may be between the redistribution layer 130 and the interposer to connect the redistribution layer 130 to the interposer.

An electronic integrated circuit chip 370 may be disposed on the stack structure 300. The electronic integrated circuit chip 370 may be contrasted with the optical integrated circuit chip 300b in that the electronic integrated circuit chip 370 includes only a circuit with an electrical integrated circuit element. The electronic integrated circuit chip 370 may include a third body 371, a connection pad 375, and a third passivation layer 377.

The third body 371 may include a circuit having a semiconductor substrate such as silicon (Si) and germanium (Ge) and a circuit having an electronic integrated circuit element.

The connection pad 375 may be disposed on a lower surface of the third body 371. The third passivation layer 377 may fill a space between the plurality of connection pads 375. The third passivation layer 377 may not cover a lower surface of the connection pad 375. The connection pad 375 may include conductive metal. The third passivation layer 377 may include an insulating material such as silicon oxide.

A third connection terminal CT3 may be disposed between the electronic integrated circuit chip 370 and the uppermost optical integrated circuit chip 300d. The third connection terminal CT3 may be connected to the connection pad 375 of the electronic integrated circuit chip 370 and the upper pad 303 of the uppermost optical integrated circuit chip 300d. The electronic integrated circuit chip 370 and the stack structure 300 may be electrically connected through the third connection terminal CT3.

A plurality of third connection terminals CT3 may be provided. A third gap fill GAP3 may fill a space between the plurality of third connection terminals CT3. The third gap fill GAP3 may mitigate or prevent electrical short circuits between the third connection terminals CT3. The third gap fill GAP3 may include an insulating material. In an example embodiment, the third gap fill GAP3 may be omitted.

A clamp 500 may be arranged on the stack structure 300 and next to the electronic integrated circuit chip 370. The clamp 500 may contact an uppermost optical fiber 400 among the optical fibers 400 and an uppermost waveguide 309 among the waveguides 309. The clamp 500 may perform a function to help ensure that the optical fibers 400 are properly fixed to the stack structure 300.

According to some example embodiments of the inventive concepts, the optical integrated circuit chip 300b of the stack structure 300 may include a groove GRV in an upper portion thereof and a notch NTC in a lower portion thereof. Accordingly, the optical fiber 400 may be coupled between the groove GRV of one optical integrated circuit chip 300b among the plurality of optical integrated circuit chips 300a, 300b, 300c, and 300d and the notch NTC of the optical integrated circuit chip 300c thereon. Additionally, one optical integrated circuit chip 300b and another optical integrated circuit chip 300c thereon may be hybrid-bonded to each other. The plurality of optical integrated circuit chips 300a, 300b, 300c, and 300d may thus be stacked in the vertical direction Z, and thus, the number of optical integrated circuit chips (e.g., 300a, 300b, 300c, and 300d) included in the stack structure 300 within the semiconductor package 1 may be increased. For the above reasons, the number of channels that the semiconductor package 1 may process may be increased, thereby increasing the data processing speed of the semiconductor package 1 and increasing the memory capacity.

Additionally, because the optical integrated circuit chips 300a, 300b, 300c, and 300d may be hybrid-bonded to each other, the electrical path between the optical integrated circuit chips 300a, 300b, 300c, and 300d may be shortened. Thus, the power efficiency of the semiconductor package 1 may be improved.

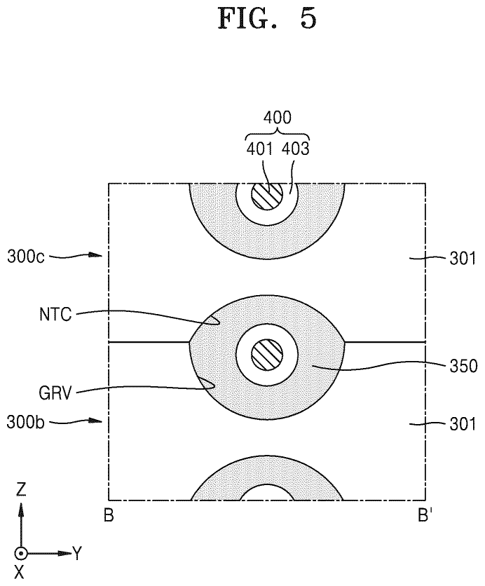

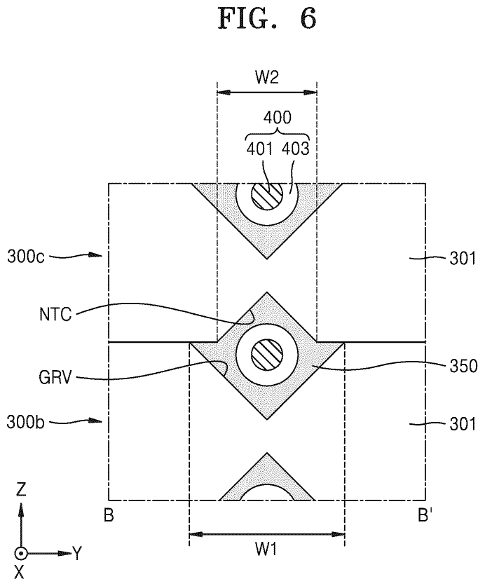

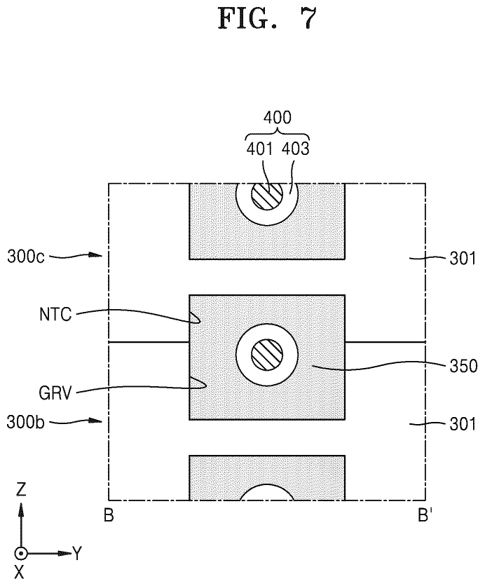

FIG. 5 is a diagram illustrating a portion of the cross-section taken along line B-B′ of FIG. 1 according to an example embodiment. FIG. 6 is a diagram illustrating a portion of the cross-section taken along line B-B′ of FIG. 1 according to an example embodiment. FIG. 7 is a diagram illustrating a portion of the cross-section taken along line B-B′ of FIG. 1 according to an example embodiment. The description of the groove GRV and the notch NTC described below is substantially the same or similar to that previously provided with reference to FIG. 4. Thus, for convenience of description, the description will focus on the differences between the groove GRV and the notch NTC of FIGS. 5 to 7 and the groove GRV and the notch NTC of FIG. 4 described above.

Referring to FIG. 5, sidewalls and bottom surfaces of the groove GRV and the notch NTC may be curved. The sidewalls and the bottom surfaces of the groove GRV and the notch NTC may be a portion of a circle or a portion of an oval. In the diagrams, the radius of curvature of the notch NTC is illustrated as being greater than the radius of curvature of the groove GRV, but the inventive concepts are not limited thereto. In some example embodiments, the radius of curvature of the notch NTC may be less than the radius of curvature of the groove GRV. This may vary depending on the design of the semiconductor package 1 to be implemented.

Referring to FIG. 6, the groove GRV may have a V shape with a sharp bottom surface, and the notch NTC may have an inverted V-shape with a sharp top surface. In other words, the sidewalls of the groove GRV may meet with each other at a bottom thereof, and the sidewalls of the notch NTC may meet with each other at a top thereof. Here, a maximum horizontal width of the groove GRV may be the first width W1 and a maximum horizontal width of the notch NTC may be the second width W2. The first width W1 may be greater than the second width W2. However, this is only an example embodiment, and the first width W1 and the second width W2 may be equal to each other, or the second width W2 may be greater than the first width W1. This may vary depending on the design of the semiconductor package 1 to be implemented.

Referring to FIG. 7, the sidewall of the groove GRV and the sidewall of the notch NTC may be formed parallel to the vertical direction Z. In other words, the groove GRV and the notch NTC may have a shape of the letter “-” rotated 90 degrees clockwise or counterclockwise. A space between the groove GRV and the notch NTC may have a “D” shape.

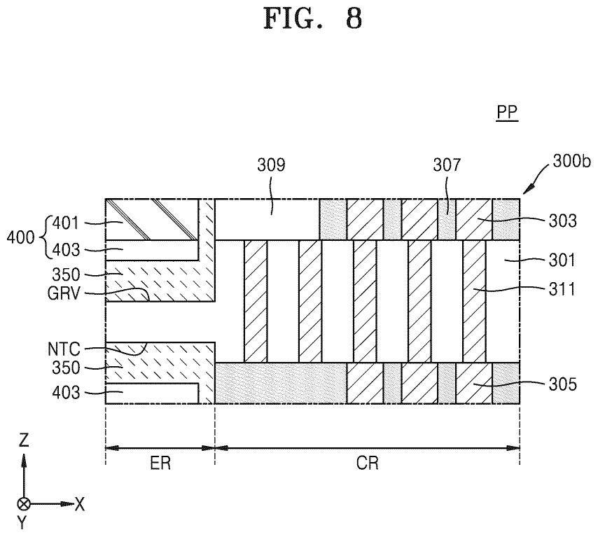

FIG. 8 is an enlarged view of the portion PP of FIG. 2 according to an example embodiment. The description of the optical resin 350, the optical fiber 400, and the waveguide 309 described below is substantially the same as or similar to that previously provided with reference to FIG. 3. Therefore, for convenience of description, description will focus on the difference between the optical resin 350, the optical fiber 400, and the waveguide 309 illustrated in FIG. 8 and the optical resin 350, the optical fiber 400, and the waveguide 309 illustrated in FIG. 3 described above.

Referring to FIG. 8, the optical resin 350 may extend between the waveguide 309 and the optical fiber 400. The waveguide 309 and the optical fiber 400 may be spaced apart from each other with the optical resin 350 therebetween. The optical resin 350 may be configured to transmit light from the optical fiber 400 to the waveguide 309. The optical resin 350 may not affect the intensity and path of light emitted from the optical fiber 400.

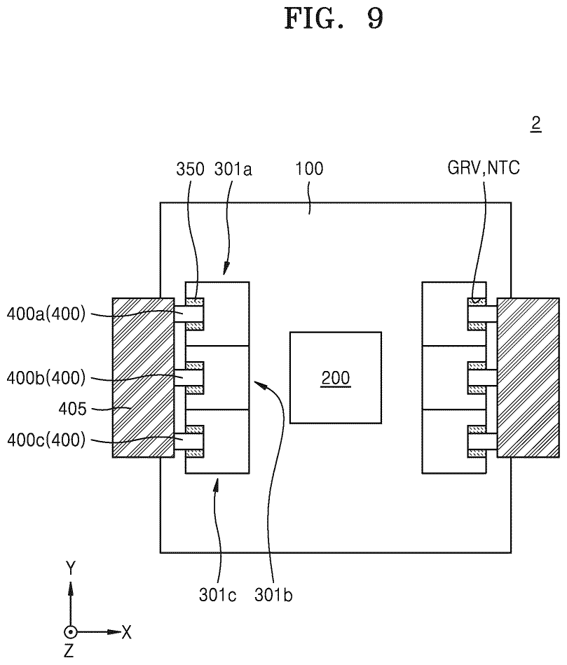

FIG. 9 is a plan view illustrating a semiconductor package according to an example embodiment. Most of the components constituting a semiconductor package 2 described below and the materials constituting the components are substantially the same or similar to those previously described with reference to FIGS. 1 to 4. Thus, for convenience of description, the description will focus on the differences between the semiconductor package 2 of FIG. 9 and the semiconductor package 1 of FIGS. 1 to 4 described above.

Referring to FIG. 9, a plurality of stack structures 301a, 301b, and 301c of the semiconductor package 2 may be arranged adjacent to each other in the first horizontal direction X or the second horizontal direction Y. Each of the stack structures 301a, 301b, and 301c of FIG. 9 may correspond to the stack structure 300 of FIGS. 1 to 4. The plurality of stack structures 301a, 301b, and 301c may be in contact with each other, but example embodiments are not limited thereto. When the plurality of stack structures 301a, 301b, and 301c are adjacent to each other in the second horizontal direction Y, first to third optical fiber bundles 400a, 400b, and 400c connected to one bracket 405 may be spaced apart from each other in the second horizontal direction Y. Each of the first to third optical fiber bundles 400a, 400b, and 400c may include a plurality of optical fibers 400 spaced apart from each other in the vertical direction Z in FIG. 2.

One bracket 405 may be arranged to correspond to the plurality of stack structures 301a, 301b, and 301c. The optical fibers 400 included in the first to third optical fiber bundles 400a, 400b, and 400c connected to the one bracket 405 may be arranged apart from each other not only in the vertical direction Z but also in the second horizontal direction Y. Accordingly, the optical fibers 400 may form a two-dimensional planar arrangement.

In this case, the number of optical fibers (400 in FIG. 2) that may be coupled to the stack structures 301a, 301b, and 301c in the same space may be increased, thereby improving the data processing speed of the semiconductor package 2 and increasing the memory capacity.

While the inventive concepts have been particularly shown and described with reference to some example embodiments thereof, it will be understood by those of ordinary skill in the art that various changes in form and details may be made therein without departing from the spirit and scope of the inventive concepts as defined by the appended claims. The disclosed example embodiments should be considered in a descriptive sense only and not for purposes of limitation.

While the inventive concepts have been particularly shown and described with reference to some example embodiments thereof, it will be understood that various changes in form and details may be made therein without departing from the spirit and scope of the following claims.

What is claimed is:

1. A semiconductor package comprising:
a redistribution layer on a substrate;
a semiconductor chip on the redistribution layer; and
a stack structure on the redistribution layer, the stack structure spaced apart from the semiconductor chip in a horizontal direction,
wherein the stack structure includes a first optical integrated circuit chip and a second optical integrated circuit chip on the first optical integrated circuit chip,
wherein each of the first optical integrated circuit chip and the second optical integrated circuit chip includes a first region and a second region,
among the first region and the second region, the first region is relatively adjacent to the semiconductor chip and the second region is relatively adjacent to an outer portion of the substrate, and
the first optical integrated circuit chip defines a first notch and a first groove in the second region, the first notch recessed upwards in a vertical direction from a lower surface of the first optical integrated circuit chip, the first groove recessed downwards in the vertical direction from an upper surface of the first optical integrated circuit chip.

2. The semiconductor package of claim 1, wherein
the second optical integrated circuit chip defines a second notch and a second groove, in the second region, the second notch recessed upwards in the vertical direction from a lower surface of the second optical integrated circuit chip, the second groove recessed downwards in the vertical direction from an upper surface of the second optical integrated circuit chip, and
the first groove and the second notch vertically overlap each other.

3. The semiconductor package of claim 2, further comprising:
an optical fiber between the first groove and the second notch.

4. The semiconductor package of claim 1, wherein the first optical integrated circuit chip is hybrid-bonded to the second optical integrated circuit chip.

5. The semiconductor package of claim 1, wherein
the first optical integrated circuit chip further includes a body and a waveguide, the waveguide being on the body and in the first region, and
the semiconductor package further comprises an optical fiber, the optical fiber being in the first groove and connected to the waveguide.

6. The semiconductor package of claim 5, wherein the first optical integrated circuit chip further includes a through via that penetrates the body and is connected to the waveguide.

7. The semiconductor package of claim 5, further comprising:
an optical resin covering a bottom surface and sidewalls of the first groove,
wherein the optical resin surrounds at least a portion of the optical fiber.

8. The semiconductor package of claim 1, wherein
the first optical integrated circuit chip further includes a body and a waveguide, the waveguide being on the body in the first region, and
the semiconductor package further comprises an optical fiber and an optical resin, the optical fiber being in the first groove and spaced apart from the waveguide in the horizontal direction, the optical resin covering a bottom surface and sidewalls of the first groove, the optical resin including a portion extending between the waveguide and the optical fiber.

9. The semiconductor package of claim 1, further comprising:
an electronic integrated circuit chip on the stack structure.

10. The semiconductor package of claim 1, wherein
the first groove has a V-shape with a flat bottom surface, and
the first notch has an inverted V-shape with a flat top surface.

11. A semiconductor package comprising:
a redistribution layer on a substrate;
a semiconductor chip on the redistribution layer;
a first stack structure on the redistribution layer and spaced apart from the semiconductor chip in a first horizontal direction; and
a plurality of first optical fibers coupled to the first stack structure,
wherein the first stack structure includes a plurality of optical integrated circuit chips stacked vertically with respect to each other, and
each of the first optical fibers is spaced apart from another in a vertical direction.

12. The semiconductor package of claim 11, wherein
each of the optical integrated circuit chips includes a first region and a second region,
among the first region and the second region, the first region is relatively adjacent to the semiconductor chip and the second region is relatively adjacent to an outer portion of the substrate, and
each of the optical integrated circuit chips defines a notch and a groove in the second region, the notch recessed upwards in the vertical direction from a lower surface of the optical integrated circuit chip, the groove recessed downwards in the vertical direction from an upper surface of the optical integrated circuit chip, and
each of the first optical fibers is between a corresponding adjacent pair of the groove and the notch.

13. The semiconductor package of claim 12, wherein
each of the optical integrated circuit chips further includes a body and a waveguide, the waveguide being on the body in the first region,
each of the first optical fibers includes a core and a cladding surrounding the core, and
the waveguide and the cladding overlap each other in the first horizontal direction.

14. The semiconductor package of claim 11, further comprising:
a connection terminal interposed between and connected to a lowermost optical integrated circuit chip, among the plurality of optical integrated circuit chips, and the redistribution layer and connected to each other,
wherein the connection terminal includes a solder bump.

15. The semiconductor package of claim 11, further comprising:
a second stack structure adjacent to the first stack structure in a second horizontal direction intersecting with the first horizontal direction, and
a plurality of second optical fibers coupled to the second stack structure.

16. The semiconductor package of claim 15, wherein
the first optical fibers are spaced apart from the second optical fibers in the second horizontal direction, respectively, and
the second optical fibers are spaced apart from each other in the vertical direction.

17. The semiconductor package of claim 15, wherein the first optical fibers and the second optical fibers are connected to one bracket.

18. A semiconductor package comprising:
a redistribution layer on a substrate;
a semiconductor chip on the redistribution layer;
a stack structure on the redistribution layer and spaced apart from the semiconductor chip in a horizontal direction; and
an electronic integrated circuit chip on the stack structure,
wherein the stack structure includes a first optical integrated circuit chip,
the first optical integrated circuit chip includes a first region and a second region, and
among the first region and the second region, the first region being relatively adjacent to the semiconductor chip and the second region being relatively adjacent to an outer portion of the substrate, and
the first optical integrated circuit chip comprises,
a first body including an optical integrated circuit and an electronic integrated circuit,
a first upper pad on an upper surface of the first body and a first lower pad on a lower surface of the first body,
a through via penetrating the first body and connected to the first upper pad and the first lower pad, and
the first optical integrated circuit chip defining a first notch and a first groove in the second region, the first notch recessed upwards in a vertical direction from a lower surface of the first optical integrated circuit chip, the first groove recessed downwards in the vertical direction from an upper surface of the first optical integrated circuit chip.

19. The semiconductor package of claim 18, further comprising:
an optical fiber in the first groove, and
a clamp in contact with the optical fiber on the first optical integrated circuit chip.

20. The semiconductor package of claim 18, wherein
the stack structure further includes a second optical integrated circuit chip on the first optical integrated circuit chip, the second optical integrated circuit chip comprising,
a second body including an optical integrated circuit and an electronic integrated circuit, and
a second upper pad on an upper surface of the second body and a second lower pad on a lower surface of the second body, and
the first upper pad and the second lower pad are in contact with each other.
